(19) United States
(12) Patent Application Publication
(10) Pub. No.: US 2012/0292742 A1
(43) Pub. Date: Nov. 22, 2012

(54) SEMICONDUCTOR DEVICE

(75) Inventors: Satomi Itoh, Osaka-shi (JP); Takeyoshi Masuda, Osaka-shi (JP)

(73) Assignee: Sumitomo Electric Industries, Ltd., Osaka-shi (JP)

(21) Appl. No.: 13/469,951

(22) Filed: May 11, 2012

Related U.S. Application Data
(60) Provisional application No. 61/488,548, filed on May 20, 2011.

(30) Foreign Application Priority Data
May 20, 2011 (JP) 2011-112964

(51) Int. Cl. H01L 29/06

(52) U.S. Cl. 257/607; 257/E29.005

(57) ABSTRACT

A MOSFET includes a silicon carbide substrate, a buffer layer made of silicon carbide formed on the silicon carbide substrate, a drift layer made of silicon carbide of an n conductivity type formed on the buffer layer, a p type body region of a p conductivity type formed in the drift layer to include a main surface of the drift layer opposite to the buffer layer, a source contact electrode formed on the p type body region, and a drain electrode formed on a main surface of the silicon carbide substrate opposite to the buffer layer. A current path region having an impurity concentration higher than that of another region in the drift layer is formed in a region in the drift layer sandwiched between the buffer layer and the body region.

### BACKGROUND OF THE INVENTION

1. Field of the Invention

The present invention relates to semiconductor devices, and more particularly to a semiconductor device capable of achieving reduction in on-resistance.

2. Description of the Background Art

Semiconductor devices, such as MOSFETs (Metal Oxide Semiconductor Field Effect Transistors) and IGBTs (Insulated Gate Bipolar Transistors), capable of controlling formation of an inversion layer by adjusting a voltage to be applied to a body region to switch between an on state and an off state, have been demanded to achieve increase in breakdown voltage, on-resistance reduction and the like. As power devices demanded to withstand large currents and high voltages, vertical semiconductor devices in which a current flows in the direction of thickness of semiconductor device are used (e.g., see Japanese Patent Laying-Open No. 2009-158788).

With recent demands for higher efficiency and smaller loss, further reduction in on-resistance has been required of the above-mentioned vertical semiconductor devices.

### SUMMARY OF THE INVENTION

The present invention was made to solve such problems, and an object of the present invention is to provide a semiconductor device capable of achieving reduction in on-resistance.

A semiconductor device according to the present invention includes a substrate made of semiconductor, a buffer layer made of semiconductor formed on the substrate, a drift layer made of semiconductor of a first conductivity type formed on the buffer layer, a body region of a second conductivity type formed in the drift layer to include a main surface of the drift layer opposite to the buffer layer, a first electrode formed on the body region, and a second electrode formed on a main surface of the substrate opposite to the buffer layer. A current path region having an impurity concentration higher than the impurity concentration of another region in the drift layer is formed in a region in the drift layer sandwiched between the buffer layer and the body region.

The semiconductor device of the present invention is a vertical semiconductor device in which a current flows between the first and second electrodes. In a conventional vertical semiconductor device, a region in the drift layer sandwiched between the buffer layer and the body region is not fully utilized as a current flow path. In contrast, in the semiconductor device of the present invention, the current path layer having a high impurity concentration is formed in the region sandwiched between the buffer layer and the body region. Accordingly, a current is led to the region sandwiched between the buffer layer and the body region, passing through the current path layer. The region in the drift layer sandwiched between the buffer layer and the body region is thereby fully utilized as a current flow path. As a result, according to the semiconductor device of the present invention, a semiconductor device capable of achieving reduction in on-resistance can be provided.

It is noted that the “impurity” mentioned above refers to a substance introduced intentionally into semiconductor for generating majority carriers.

In the semiconductor device described above, the impurity concentration of the current path region may be lower than the impurity concentration of the buffer layer. In the semiconductor device described above, the impurity concentration of the current path region may be higher at a side closer to the buffer layer than at a side closer to the body region. Consequently, an electric field concentration can be eased. It is noted that the impurity concentration of the current path region may be increased gradually or stepwise from the body region side to the buffer layer side. In the semiconductor device described above, the current path region may be formed by epitaxial growth. The current path region can thereby be formed easily. It is noted that the current path region may be formed by ion implantation, for example.

In the semiconductor device described above, a distance between the body region and the current path region may be smaller than the distance between the buffer layer and the current path region. Consequently, the region in the drift layer sandwiched between the buffer layer and the body region can be utilized more efficiently as a current flow path.

The semiconductor device described above may be a DiMOSFET (Double Implanted MOSFET). The semiconductor device of the present invention is suitable for a structure of a DiMOSFET.

As is clear from the description above, according to the semiconductor device of the present invention, a semiconductor device capable of achieving reduction in on-resistance can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a structure of a MOSFET.

FIG. 2 is a flowchart schematically illustrating a method of manufacturing the MOSFET.

FIG. 3 is a schematic cross-sectional view for explaining the method of manufacturing the MOSFET.

FIG. 4 is a schematic cross-sectional view for explaining the method of manufacturing the MOSFET.

FIG. 5 is a schematic cross-sectional view for explaining the method of manufacturing the MOSFET.

### DESCRIPTION OF THE PREFERRED EMBODIMENTS

An embodiment of the present invention will be described hereinafter with reference to the drawings. It is noted that the same or corresponding parts have the same reference numerals allotted in the drawings, and description thereof will not be repeated.

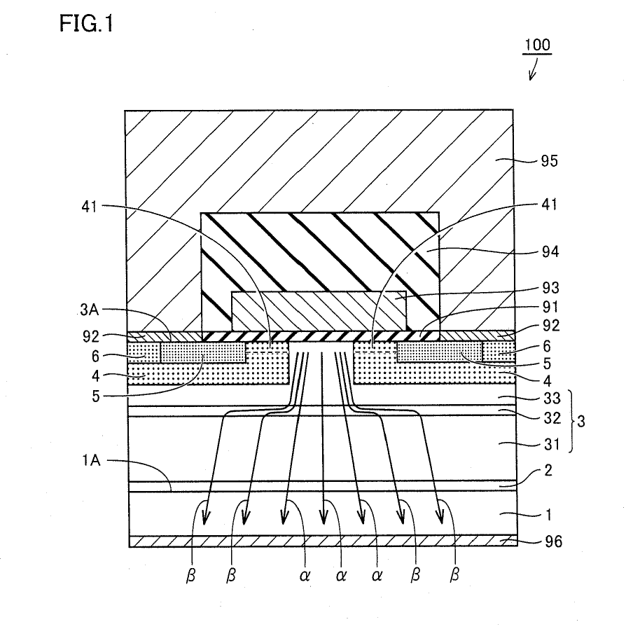

Referring to FIG. 1, a semiconductor device of one embodiment of the present invention will be described. A MOSFET 100 which is a semiconductor device (DiMOSFET) in this embodiment includes a silicon carbide substrate 1 of an n conductivity type (first conductivity type), a buffer layer 2 of the n conductivity type made of silicon carbide, a drift layer 3 of the n conductivity type made of silicon carbide, a pair of p type body regions 4 of a p conductivity type (second conductivity type), n⁺ regions 5 of the n conductivity type, and p⁺ regions 6 of the p conductivity type.

Buffer layer 2 is formed on one main surface 1A of silicon carbide substrate 1, and is of the n conductivity type by containing an n type impurity. Drift layer 3 is formed on buffer layer 2, and is of the n conductivity type by containing an n type impurity. The n type impurity contained in drift layer 3 is N (nitrogen), for example, and contained in a concentration (density) lower than that of the n type impurity contained in buffer layer 2. Buffer layer 2 and drift layer 3 constitute an epitaxial growth layer formed on one main surface 1A of silicon carbide substrate 1.

In a region of drift layer 3 sandwiched between buffer layer 2 and p type body regions 4, a current path layer 32 as a current path region having an impurity concentration higher than that of other regions in drift layer 3 is formed. More specifically, drift layer 3 includes a first drift layer 31 arranged on and in contact with buffer layer 2, current path layer 32 as a current path region arranged on first drift layer 31, and a second drift layer 33 arranged on current path layer 32. First drift layer 31 can have an impurity concentration of approximately not less than 1.0×10¹⁴cm³ and not more than 1.0×10¹⁶cm⁻³, for example. Second drift layer 33 can have an impurity concentration of approximately not less than 1.0×10¹⁴ cm³and not more than 2.0×10 ¹⁸ cm³, for example. Current path layer 32 can have an impurity concentration of approximately not less than 1.0×10¹⁶ cm³ and not more than 1.0×10¹⁸cm³, for example. Current path layer 32 can have a thickness of approximately not less than 0.1 μm and not more than 2.0 μm. Further, the distance between current path layer 32 and p type body regions 4 can be approximately not less than 0.05 μm and not more than 0.5 μm, for example. More preferably, if the relation that the impurity concentration is higher in second drift layer 33 than in first drift layer 31 is met, JFET resistance can be reduced. More preferably, if the relation that the impurity concentration of current path layer 32 is not less than that of second drift layer 33 is met, an electric field concentration on an oxide film directly above a JFET region can be eased while obtaining the current spread effect.

The pair of p type body regions 4 is formed apart from each other in the epitaxial growth layer (drift layer 3) to include a main surface 3A opposite to a main surface closer to silicon carbide substrate 1, and is of the p conductivity type by containing a p type impurity (an impurity of the p conductivity type). The p type impurity contained in p type body regions 4 is aluminum (Al) and/or boron (B), for example.

Each of n⁺ regions 5 is formed in each of the pair of p type body regions 4 to include main surface 3A and be surrounded by each of p type body regions 4. N⁺ regions 5 contain an n type impurity such as P in a concentration (density) higher than that of the n type impurity contained in drift layer 3. Each of p⁺ regions 6 is formed in each of the pair of p type body regions 4 to include main surface 3A, be surrounded by each of p type body regions 4, and be adjacent to each of n⁺ regions 5. P⁺ regions 6 contain a p type impurity such as A1 in a concentration (density) higher than that of the p type impurity contained in p type body regions 4.

Referring to FIG. 1, MOSFET 100 further includes a gate oxide film 91 as a gate insulating film, a gate electrode 93, a pair of source contact electrodes 92, an interlayer insulating film 94, a source line 95, and a drain electrode 96. Gate oxide film 91 is formed on and in contact with main surface 3A of the drift layer to extend from an upper surface of one of n⁺ regions 5 to an upper surface of the other n⁺ region 5, and is made of silicon dioxide (SiO₂), for example. Gate electrode 93 is arranged in contact with gate oxide film 91 to extend from above one of n⁺ regions 5 to above the other n⁺ region 5. Gate electrode 93 is formed of a conductor such as polysilicon including an impurity or A1.

Each of source contact electrodes 92 is arranged in contact with main surface 3A to extend from above each of the pair of n⁺ regions 5 in a direction away from gate oxide film 91 to reach a portion above each of p⁺ regions 6. Source contact electrodes 92 are made of a material capable of making ohmic contact with n⁺ regions 5, such as NiₓSi_{y} (nickel silicide).

Interlayer insulating film 94 is formed to surround gate electrode 93 above main surface 3A of drift layer 3 and extend from above one of p type body regions 4 to above the other p type body region 4, and is made of silicon dioxide (SiO₂) which is an insulator, for example.

Source line 95 surrounds interlayer insulating film 94 above main surface 3A of drift layer 3, and extends to upper surfaces of source contact electrodes 92. Source line 95 is formed of a conductor such as A1, and electrically connected to n⁺ regions 5 via source contact electrodes 92.

Drain electrode 96 is formed in contact with a main surface of silicon carbide substrate 1 opposite to the surface on which drift layer 3 is formed. Drain electrode 96 is made of a material capable of making ohmic contact with silicon carbide substrate 1, such as NiₓSi_{y}, and electrically connected to silicon carbide substrate 1. Next, operation of MOSFET 100 will be described. Referring to FIG. 1, when gate electrode 93 has a voltage lower than a threshold voltage, i.e., in an off state, a pn junction between each of p type body regions 4 and drift layer 3 positioned immediately below gate oxide film 91 is reverse biased and non-conducting even if a voltage is applied to the drain electrode. On the other hand, when a voltage higher than the threshold voltage is applied to gate electrode 93, an inversion layer is formed in a channel region 41 in p type body region 4 which is in contact with gate oxide film 91. As a result, n⁺ regions 5 and drift layer 3 are electrically connected to each other, causing a current to flow between source line 95 and drain electrode 96.

In MOSFET 100 in an on state, electrons supplied from source line 95 pass through source contact electrodes 92, n⁺ regions 5, channel region 41 with the inversion layer formed therein, drift layer 3, buffer layer 2, and silicon carbide substrate 1 to reach drain electrode 96. In a conventional MOSFET in which current path layer 32 as a current path region is not formed, referring to FIG. 1, electrons having passed through channel region 41 to reach a region in drift layer 3 sandwiched between p type body regions 4 opposed to each other will head toward drain electrode 96 passing through drift layer 3, buffer layer 2, and silicon carbide substrate 1 while slightly expanding their flow paths along arrows α. As a result, a region in drift layer 3 sandwiched between buffer layer 2 and p type body regions 4 will not be fully utilized as a current flow path.

In contrast, in MOSFET 100 of the present embodiment, current path layer 32 as a current path region having a high impurity concentration is formed in the region sandwiched between buffer layer 2 and p type body regions 4. More specifically, current path layer 32 is formed in drift layer 3 to extend from the region where buffer layer 2 and p type body regions 4 are opposed to each other to a region where buffer layer 2 and gate oxide film 91 are opposed to each other. Explaining from another point of view, current path layer 32 is formed along the main surface of buffer layer 2 as a single layer extending substantially in parallel with a main surface of buffer layer 2. Therefore, electrons arrived at second drift layer 33 not only move along arrows α, but also significantly expand their flow paths in current path layer 32 along arrows 13, and pass through first drift layer 31, buffer layer 2, and silicon carbide substrate 1 to head toward drain electrode 96. The region in drift layer 3 sandwiched between buffer layer 2 and p type body regions 4 is thereby fully utilized as a current flow path. As a result, MOSFET 100 of the present embodiment is a semiconductor device capable of achieving reduction in on-resistance.

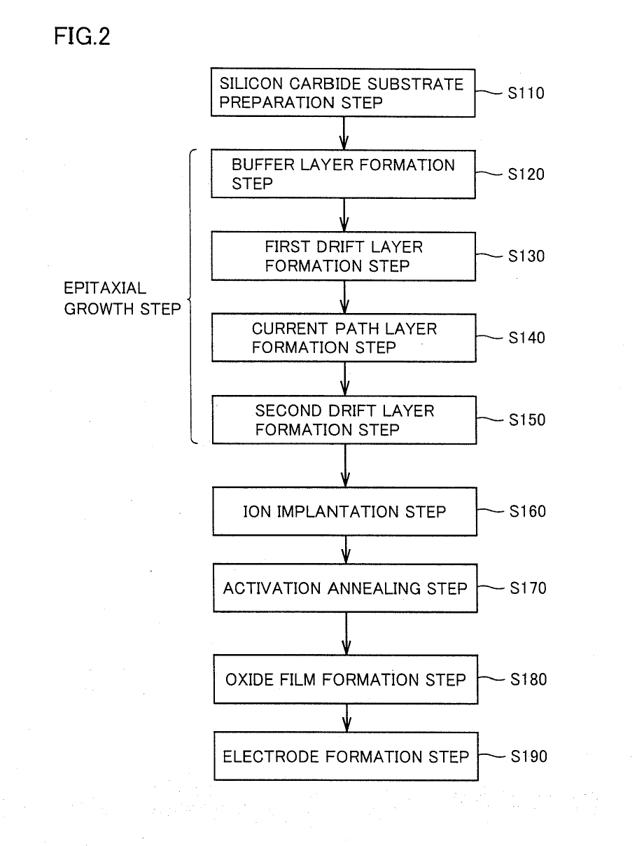

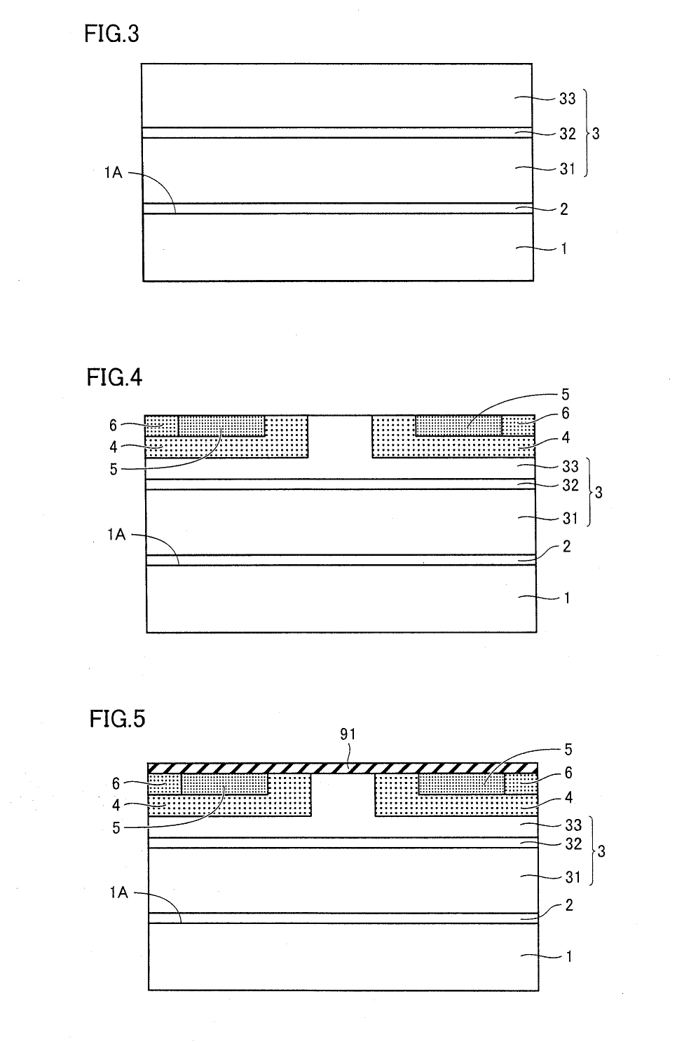

Next, an exemplary method of manufacturing MOSFET 100 in this embodiment will be described with reference to FIGS. 2 to 5. Referring to FIG. 2, in the method of manufacturing MOSFET 100 in this embodiment, a silicon carbide substrate preparation step is first performed as a step (S110). In this step (S110), referring to FIG. 3, silicon carbide substrate 1 made of single-crystalline silicon carbide and having an n type conductivity is prepared. Next, an epitaxial growth step is performed. In this epitaxial growth step, a buffer layer formation step as a step (S120), a first drift layer formation step as a step (S130), a current path layer formation step as a step (S140), and a second drift layer formation step as a step (S150) are performed successively. In these steps (S120) to (S150), referring to FIG. 3, silicon carbide is epitaxially grown on one main surface 1A of silicon carbide substrate 1 while introducing an impurity in accordance with each layer, thereby successively forming buffer layer 2, first drift layer 31, current path layer 32, and second drift layer 33. Buffer layer 2 and drift layer 3 are thereby formed on silicon carbide substrate 1.

Next, an ion implantation step is performed as a step (S160). In this step (S160), referring to FIGS. 3 and 4, ion implantation for forming p type body regions 4 is first performed. Specifically, Al (aluminum) ions are implanted into drift layer 3 (second drift layer 33), for example, to form p type body regions 4. Then, ion implantation for forming n⁺ regions 5 is performed. Specifically, P (phosphor) ions are implanted into p type body regions 4, for example, to form n⁺ regions 5 in p type body regions 4. Further, ion implantation for forming p⁺ regions 6 is performed.

Specifically, Al ions are implanted into p type body regions 4, for example, to form p⁺ regions 6 in p type body regions 4. Each of these ion implantations can be performed by forming a mask layer, which is made of silicon dioxide (SiO₂) and has an opening in a desired region where the ion implantation should be performed, on a main surface of drift layer 3, for example.

Next, an activation annealing step is performed as a step (S170). In this step (S170), heat treatment is conducted by heating to 1700° C. in an atmosphere of inert gas such as argon and maintaining the temperature for 30 minutes, for example. As a result, the impurities implanted in the above step (S160) are activated.

Next, an oxide film formation step is performed as a step (S180). In this step (S180), referring to FIGS. 4 and 5, heat treatment is conducted by heating to 1300° C. in an oxygen atmosphere and maintaining the temperature for 60 minutes, for example, to form oxide film (gate oxide film) 91.

Next, an electrode formation step is performed as a step (S190). Referring to FIG. 1, in this step (S190), gate electrode 93 made of polysilicon which is a conductor including a highly concentrated impurity is formed by a CVD method, photolithography and etching, for example. Then, interlayer insulating film 94 made of SiO₂ which is an insulator is formed by a CVD method, for example, to surround gate electrode 93 above main surface 3A. Then, interlayer insulating film 94 and oxide film 91 in a region where source contact electrodes 92 are to be formed are removed by photolithography and etching. Then, a nickel (Ni) film formed by an evaporation method, for example, is heated and silicidized, to form source contact electrodes 92 and drain electrode 96. Then, source line 95 made of Al which is a conductor is formed by an evaporation method, for example, to surround interlayer insulating film 94 above main surface 3A and extend to the upper surfaces of n⁺ regions 5 and source contact electrodes 92. Following the above procedure, MOSFET 100 in this embodiment is completed. In MOSFET 100, current path layer 32 may have an impurity concentration lower than that of buffer layer 2. In MOSFET 100, current path layer 32 may have an impurity concentration higher at buffer layer 2 side than at p type body regions 4 side. Consequently, an electric field concentration can be eased. In order to change the impurity concentration in current path layer 32 as described above, when forming current path layer 32 by epitaxial growth, for example, current path layer 32 may be grown while changing the concentration of each impurity to be introduced to have a desired concentration.

In MOSFET 100, the distance between p type body regions 4 and current path layer 32 may be smaller than that between buffer layer 2 and current path layer 32. The region in drift layer 3 sandwiched between buffer layer 2 and p type body regions 4 can thereby be utilized more efficiently as a current flow path.

It is noted that, although the above embodiment has described the case where silicon carbide is employed as semiconductor constituting the substrate, the buffer layer and the drift layer, the semiconductor material that can be employed in the semiconductor device of the present invention is not limited to this, but may be silicon or gallium nitride, for example. On the other hand, when silicon carbide is employed as described above, the silicon carbide is preferably a hexagonal crystal, and more specifically, 4H-SiC is preferably employed. In addition, although the above embodiment has described the MOSFET as an example of semiconductor device, it may be an IGBT or the like, for example.

Further, the above embodiment has described the case where current path layer 32 is formed as a continuous layer as a current path region, however, the current path region that can be employed in the present invention is not limited to this. Specifically, current path regions apart from each other may be formed, each being provided for the buffer layer and each opposed body region, for example.

The method of forming the current path region is not limited to epitaxial growth, but may be accomplished by ion implantation, for example. The semiconductor device of the present invention is applicable particularly advantageously to a semiconductor device requested to achieve reduction in on-resistance.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a substrate made of semiconductor;
a buffer layer made of semiconductor formed on said substrate;
a drift layer made of semiconductor of a first conductivity type formed on said buffer layer;
a body region of a second conductivity type formed in said drift layer to include a main surface of said drift layer opposite to said buffer layer;
a first electrode formed on said body region; and
a second electrode formed on a main surface of said substrate opposite to said buffer layer,
a current path region having an impurity concentration higher than the impurity concentration of another region in said drift layer being formed in a region in said drift layer sandwiched between said buffer layer and said body region.

2. The semiconductor device according to claim 1, wherein the impurity concentration of said current path region is lower than the impurity concentration of said buffer layer.

3. The semiconductor device according to claim 1, wherein the impurity concentration of said current path region is higher at a side closer to said buffer layer than at a side closer to said body region.

4. The semiconductor device according to claim 1, wherein said current path region is formed by epitaxial growth.

5. The semiconductor device according to claim 1, wherein a distance between said body region and said current path region is smaller than the distance between said buffer layer and said current path region.
